(19) United States
(12) Patent Application Publication
(10) Pub. No.: US 2008/0128022 A1
(43) Pub. Date: Jun. 5, 2008

(54) Photovoltaic device including a tin oxide protective layer

(75) Inventors: Dale Roberts, Temperance, MI (US); Upali Jayamaha, Toledo, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 11/937,147

(22) Filed: Nov. 8, 2007

Related U.S. Application Data
(60) Provisional application No. 60/865,948, filed on Nov. 15, 2006.

(51) Int. Cl. H01L 31/0296

(52) U.S. Cl. 136/260; 136/252; 438/86; 257/E31.015

(57) ABSTRACT

A photovoltaic device can include a protective layer including a tin oxide over a transparent conducting layer to stabilize the transparent conducting layer.

### CLAIM FOR PRIORITY

This application claims priority under 35 U.S.C. § 119(e) to Provisional U.S. Patent Application Ser. No. 60/865,948 filed on Nov. 15, 2006, which is hereby incorporated by reference.

### TECHNICAL FIELD

This invention relates to photovoltaic devices.

### BACKGROUND

During the fabrication of photovoltaic devices, layers of semiconductor material can be applied to a substrate with one layer serving as a window layer and a second layer serving as the absorber layer. The window layer allows the penetration of solar energy to the absorber layer, where the energy is converted into electrical energy. In order to enhance performance of the photovoltaic device, it can be desirable to use layers that have good electrical and optical properties as well as thermal and chemical stability.

### SUMMARY

In general, a conductive surface includes a transparent conductive layer on a surface of a substrate, and a protective layer over the transparent conductive layer, the protective layer isolating the transparent conductive layer. The protective layer can include a tin oxide. For example, a photovoltaic device can include a transparent conductive layer on a surface of a substrate, a first semiconductor layer, and a protective layer between the transparent conductive layer and the first semiconductor layer, the protective layer isolating the transparent conductive layer. The protective layer can include a tin oxide.

A system for generating electrical energy can include a multilayered photovoltaic device, the photovoltaic device including a transparent conductive layer on a surface of a substrate, a first semiconductor layer, and a protective layer between the transparent conductive layer and the first semiconductor layer, the protective layer isolating the transparent conductive layer. The protective layer can include a tin oxide, and electrical connections connected to the photovoltaic device for collecting electrical energy produced by the photovoltaic device.

A method of making a photovoltaic device substrate can include placing a transparent conductive layer on a surface of a substrate, placing a first semiconductor layer on a substrate, and placing a protective layer including a tin oxide between the transparent conductive layer and the first semiconductor layer, the protective layer isolating the transparent conductive layer.

The transparent conductive layer can include a transparent conductive oxide. The transparent conductive oxide can be substantially tin-free. The transparent conductive layer can include an aluminum doped zinc oxide.

The protective layer can include zinc. The protective layer can include an amount of zinc, such as 1% zinc. The protective layer can have a thickness of less than 1200 Angstroms. The protective layer can have a thickness of less than 600 Angstroms. The protective layer can chemically isolate the transparent conductive layer from a semiconductor layer.

The photovoltaic device can be chemically stable at temperatures greater than 500° C. The photovoltaic device can be thermally stable at temperatures greater than 500° C.

The first semiconductor layer can include a binary semiconductor. The first semiconductor layer can include CdS or CdTe. The photovoltaic device can also include a second semiconductor layer over the first semiconductor layer. The second semiconductor layer can include a binary semiconductor. The second semiconductor layer can include CdTe.

The details of one or more embodiments are set forth in the accompanying drawings and the description below. Other features, objects, and advantages will be apparent from the description and drawings, and from the claims.

### DESCRIPTION OF DRAWINGS

FIG. 1 is a schematic of a substrate with multiple layers.

### DETAILED DESCRIPTION

A photovoltaic device can be constructed of a series of layers of semiconductor materials deposited on a glass substrate. In an example of a common photovoltaic device, the multiple layers can include: a bottom layer that is a transparent conductive layer, a protective layer, a window layer, an absorber layer and a top layer. Each layer can be deposited at a different deposition station of a manufacturing line with a separate deposition gas supply and a vacuum-sealed deposition chamber at each station as required. The substrate can be transferred from deposition station to deposition station via a rolling conveyor until all of the desired layers are deposited. Additional layers can be added using other techniques such as sputtering. Electrical conductors can be connected to the top and the bottom layers respectively to collect the electrical energy produced when solar energy is incident onto the absorber layer. A top substrate layer can be placed on top of the top layer to form a sandwich and complete the photovoltaic device.

The bottom layer can be a transparent conductive layer, and can be for example a transparent conductive oxide such as zinc oxide, zinc oxide doped with aluminum, tin oxide or tin oxide doped with fluorine. A zinc oxide doped with aluminum can have an aluminum level of less than 5 percent by weight, less than 3 percent by weight, less than 1 percent by weight, less than 2 percent by weight, more than 0 percent by weight, more than 0.2 percent by weight, more than 0.5 percent by weight, or more than 1 percent by weight, for example. Sputtered aluminum doped zinc oxide has good electrical and optical properties, but at temperatures greater than 500° C., aluminum doped zinc oxide can exhibit chemical instability. In addition, at processing temperatures greater than 500° C., oxygen and other reactive elements can diffuse into the transparent conductive oxide, disrupting its electrical properties.

In addition, deposition of a semiconductor layer at high temperature directly on the transparent conductive oxide layer can result in reactions that negatively impact the performance and stability of the photovoltaic device. Deposition of a protective layer of material with a high chemical stability such as tin oxide, silicon dioxide, dialuminum trioxide, titanium dioxide, diboron trioxide and other similar entities, can significantly reduce the impact of these reactions on device performance and stability. A protective layer can be deposited in addition to or in place of a capping layer. Capping layers are described, for example, in U.S. Patent Publication 20050257824, which is incorporated by reference herein.

Chemical and electrical stability of the transparent conductive layer can be improved by applying a protective layer, such as a protective tin oxide layer. The protective layer can chemically or thermally isolate the transparent conductive layer. The transparent conductive layer can be a transparent conductive oxide, such a zinc oxide or aluminum doped zinc oxide. The transparent conductive oxide can be substantially tin free. By adding an amount of zinc, such as 1% zinc, to the protective layer, the diffusion of zinc from the aluminum doped zinc oxide (ZnO:Al) to a protective layer can be reduced. Other amounts of zinc may be added, such as 5%, 2%, 1%, or less than 1%. The protective layer can also serve as a buffer layer to enhance the efficiency of a photovoltaic device.

The thickness of the protective layer can be from greater than about 10 Å. In certain circumstances, the thickness of the protective layer can be less than about 1200 Å, or less than about 600 Å. For example, the thickness of the protective layer can be greater than 20 Å, greater than 50 Å, greater than 75 Å or greater than 100 Å. For example, the thickness of the protective layer can be less than 250 Å, less than 200 Å, less than 150 Å, less than 125 Å, less than 100 Å, less than 75 Å or less than 50 Å. The thickness of the protective layer can be such that complete coverage of the transparent conductive oxide layer will occur. The protective layer can reduce the surface roughness of the transparent conductive oxide layer by filling in irregularities in the surface, which can aid in deposition of the window layer and can allow the window layer to have a thinner cross-section. The reduced surface roughness can help improve the uniformity of the window layer. Other advantages of including the protective layer in photovoltaic devices can include improving optical clarity, improving grading in band gap, providing better field strength at the junction and providing better device efficiency as measured by open circuit voltage gain under simulated sunlight, for example.

The window layer and the absorbing layer can include, for example, a binary semiconductor such as group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof. An example of a window layer and absorbing layer is a layer of CdS coated by a layer of CdTe. A top layer can cover the semiconductor layers. The top layer can include a metal such as, for example, nickel or aluminum.

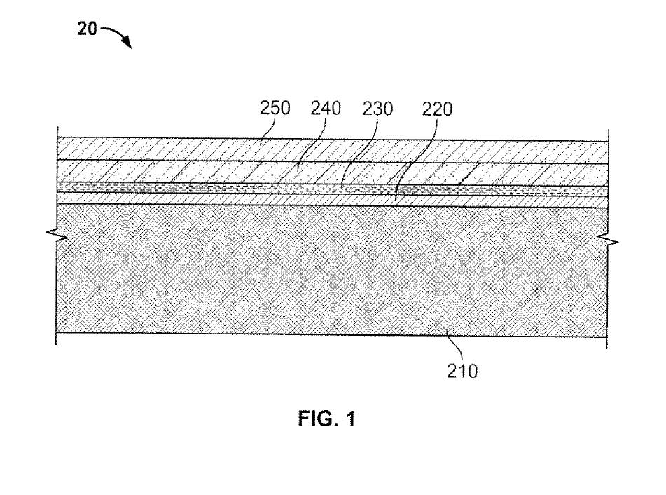

Referring to FIG. 1, a cross section of the multiple layers of a photovoltaic device 20 has substrate 210 upon which are deposited the layers used in the photovoltaic device. The first layer deposited on the substrate is a thin film of a transparent conductive layer 220. This layer 220 can be a transparent conductive oxide, such as a metallic oxide such as zinc oxide, or a tin-free oxide, which can be doped, for example, with aluminum. Protective layer 230 can be deposited between a transparent conductive layer 220 and a first semiconductor layer 240, and can have resistivity sufficiently high to reduce the effects of pinholes in the first semiconductor layer. Pinholes in the first semiconductor layer 240 can result in shunt formation between a second semiconductor layer 250 and the first contact resulting in a drain on the local field surrounding the pinhole. A small increase in the resistance of this pathway can dramatically reduce the area affected by the shunt. The protective layer 230 can be deposited over a transparent conductive layer. The protective layer can be deposited between a first semiconductor layer and a transparent conductive layer. The protective layer can be a very thin layer of a material with high chemical stability. For example, a protective layer 230 can be a protective layer of tin oxide including an amount of zinc, such as 1% zinc, provided for thermal and chemical stability. The protective layer 230 can have higher transparency than a comparable thickness of semiconductor material having the same thickness.

Other examples of materials that are suitable for use as a protective layer include silicon dioxide, dialuminum trioxide, titanium dioxide, diboron trioxide and other similar entities. Protective layer 230 can also serve to isolate the transparent conductive layer 220 electrically and chemically from the first semiconductor layer 240 preventing reactions that occur at high temperature that can negatively impact performance and stability. The protective layer 230 can also provide a conducive surface that can be more suitable for accepting deposition of the first semiconductor layer 240. For example, the protective layer 230 can provide a surface with decreased surface roughness.

In certain circumstances, a capping layer can be deposited in addition to a tin oxide protective layer. A capping layer can be positioned between the transparent conductive layer and the window layer. The capping layer can be positioned between the protective layer and the window layer. The capping layer can be positioned between the transparent conductive layer and the protective layer. The capping layer can serve as a buffer layer, which can allow a thinner window layer to be used. For example, when using a capping layer and a protective layer 230, the first semiconductor layer 240 can be thinner than in the absence of the buffer layer. For example, the first semiconductor layer 240 can have a thickness of greater than about 10 nm and less than about 600 nm. For example, the first semiconductor layer can have a thickness greater than 20 nm, greater than 50 nm, greater than 100 nm, or greater than 200 nm and less than 400 nm, less than 300 nm, less than 250 nm, or less than 150 nm.

The first semiconductor layer 240 can serve as a window layer for the second semiconductor layer 250. By being thinner, the first semiconductor layer 240 allows greater penetration of the shorter wavelengths of the incident light to the second semiconductor layer 250. The first semiconductor layer 240 can be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof. It can be a binary semiconductor, for example it can be CdS. The second semiconductor layer 250 can be deposited onto the first semiconductor layer 240. The second semiconductor 250 can serve as an absorber layer for the incident light when the first semiconductor layer 240 is serving as a window layer. Similar to the first semiconductor layer 240, the second semiconductor layer 250 can also be a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or mixtures thereof.

Deposition of semiconductor layers in the manufacture of photovoltaic devices is described, for example, in U.S. Pat. Nos. 5,248,349, 5,372,646, 5,470,397, 5,536,333, 5,945,163, 6,037,241, and 6,444,043, each of which is incorporated by reference in its entirety. The deposition can involve transport of vapor from a source to a substrate, or sublimation of a solid in a closed system. An apparatus for manufacturing photovoltaic devices can include a conveyor, for example a roll conveyor with rollers. Other types of conveyors are possible. The conveyor transports substrate into a series of one or more deposition stations for depositing layers of material on the exposed surface of the substrate. The deposition chamber can be heated to reach a processing temperature of not less than about 450° C. and not more than about 700° C., for example the temperature can range from 450-550, 550-650°, 570-600° C., 600-640° C. or any other range greater than 450° C. and less than about 700° C. The deposition chamber includes a deposition distributor connected to a deposition vapor supply. The distributor can be connected to multiple vapor supplies for deposition of various layers or the substrate can be moved through multiple and various deposition stations each station with its own vapor distributor and supply. The distributor can be in the form of a spray nozzle with varying nozzle geometries to facilitate uniform distribution of the vapor supply.

Devices including protective layers can be fabricated using soda lime float glass as a substrate. A film of ZnO:Al can be commercially deposited by sputtering or by atmospheric pressure chemical vapor deposition (APCVD). Other doped transparent conducting oxides, such as a tin oxide can also be deposited as a film. Conductivity and transparency of this layer suit it to serving as the front contact layer for the photovoltaic device.

A second layer of a transparent conducting oxide, such as tin oxide, or tin oxide with zinc can be deposited. This layer is transparent, but conductivity of this layer is significantly lower than an aluminum-doped ZnO layer or a fluorine doped SnO₂ layer, for example. This second layer can also serve as a buffer layer, since it can be used to prevent shunting between the transparent contact and other critical layers of the device. The protective layers were deposited in house by sputtering onto aluminum-doped ZnO layers during device fabrication for these experiments. The protective layers were deposited at room temperature. A silicon dioxide capping layer can be deposited over a transparent conducting oxide using electron-beam evaporation.

Devices can be finished with appropriate back contact methods known to create devices from CdTe PV materials. Testing for results of these devices was performed at initial efficiency, and after accelerated stress testing using I/V measurements on a solar simulator. Testing for impact of chemical breakdown in the front contact and protective layers was done with spectrophotometer reflectance measurements, conductivity (sheet resistance) measurements.

A tin oxide protective layer has been shown to improve module efficiency. For example, 1000 nm thick ZnO:Al films coated on borosilicate glass with a tin oxide protective layer exhibited a module efficiency of 8.97%, compared to a 2.74% efficiency for modules without a tin oxide protective layer.

A tin oxide protective layer has also been shown to improve thermal stability. For example, when tin oxide protective layers ranging from 600-1200 Angstroms in thickness were deposited onto 1000 nm thick ZnO:Al films and subjected to high temperature processing (500° C.), the sample sheet resistivity with the tin oxide protective layer was shown to be two to three times less than the samples without the tin oxide protective layers. Several samples having tin oxide protective layer did not exhibit an increase in sheet resistance.

A number of embodiments have been described. Nevertheless, it will be understood that various modifications may be made without departing from the spirit and scope of the invention. For example, the semiconductor layers can include a variety of other materials, as can the materials used for the buffer layer and the protective layer. Accordingly, other embodiments are within the scope of the following claims.

What is claimed is:

1. A photovoltaic device comprising:
a transparent conductive layer on a surface of a substrate;
a first semiconductor layer; and
a protective layer between the transparent conductive layer and the first semiconductor layer, the protective layer isolating the transparent conductive layer, wherein the protective layer includes a tin oxide.

2. The photovoltaic device of claim 1 wherein the transparent conductive layer comprises a transparent conductive oxide.

3. The photovoltaic device of claim 2, wherein the transparent conductive oxide is substantially tin-free.

4. The photovoltaic device of claim 1 wherein the transparent conductive layer comprises an aluminum doped zinc oxide.

5. The photovoltaic device of claim 1 wherein the protective layer further comprises zinc.

6. The photovoltaic device of claim 1 wherein the protective layer further comprises 1% zinc.

7. The photovoltaic device of claim 1 wherein the protective layer has a thickness of less than 1200 Angstroms.

8. The photovoltaic device of claim 1 wherein the protective layer has a thickness of less than 600 Angstroms.

9. The photovoltaic device of claim 1 wherein the substrate is chemically stable at temperatures greater than 500° C.

10. The photovoltaic device of claim 1 wherein the substrate is thermally stable at temperatures greater than 500° C.

11. The photovoltaic device of claim 1 wherein the protective layer chemically isolates the transparent conductive layer from a semiconductor layer.

12. The photovoltaic device of claim 1 wherein the first semiconductor layer comprises a binary semiconductor.

13. The photovoltaic device of claim 1 wherein the first semiconductor layer comprises CdS.

14. The photovoltaic device of claim 1 wherein the first semiconductor layer comprises CdTe.

15. The photovoltaic device of claim 1 further comprising a second semiconductor layer over the first semiconductor layer.

16. The photovoltaic device of claim 15 wherein the second semiconductor layer comprises a binary semiconductor.

17. The photovoltaic device of claim 15 wherein the second semiconductor layer comprises CdTe.

18. A system for generating electrical energy comprising:
a multilayered photovoltaic device, the photovoltaic device including
a transparent conductive layer on a surface of a substrate,
a first semiconductor layer, and
a protective layer between the transparent conductive layer and the first semiconductor layer, the protective layer isolating the transparent conductive layer, wherein the protective layer includes a tin oxide; and
electrical connections connected to the photovoltaic device for collecting electrical energy produced by the photovoltaic device.

19. The system of claim 18 wherein the transparent conductive layer comprises a transparent conductive oxide.

20. The system of claim 18 wherein the transparent conductive oxide is substantially tin-free.

21. The system of claim 18 wherein the transparent conductive layer comprises an aluminum doped zinc oxide.

22. The system of claim 18 wherein the protective layer further comprises zinc.

23. The system of claim 18 wherein the protective layer further comprises 1% zinc.

24. The system of claim 18 wherein the protective layer has a thickness of less than 1200 Angstroms.

25. The system of claim 18 wherein the protective layer has a thickness of less than 600 Angstroms.

26. The system of claim 18 wherein the substrate is chemically stable at temperatures greater than 500° C.

27. The system of claim 18 wherein the substrate is thermally stable at temperatures greater than 500° C.

28. The system of claim 18 wherein the first semiconductor layer comprises a binary semiconductor.

29. The system of claim 18 wherein the first semiconductor comprises CdS.

30. The system of claim 18 wherein the first semiconductor comprises CdTe.

31. The system of claim 18 wherein the photovoltaic device further comprises a second semiconductor layer on top of the first semiconductor layer.

32. The system of claim 31 wherein the second semiconductor layer comprises a binary semiconductor.

33. The system of claim 31 wherein the second semiconductor layer comprises CdTe.

34. A method of making a photovoltaic device substrate comprising:
placing a transparent conductive layer on a surface of a substrate;
placing a first semiconductor layer on a substrate;
placing a protective layer including a tin oxide between the transparent conductive layer and the first semiconductor layer, the protective layer isolating the transparent conductive layer.

35. The method of claim 34 wherein placing a transparent conductive layer includes depositing a uniform layer of a transparent conductive oxide on the substrate by sputtering.

36. The method of claim 34, wherein the transparent conductive oxide is substantially tin-free.

37. The method of claim 34 wherein the transparent conductive oxide comprises aluminum-doped zinc oxide.

38. The method of claim 34 wherein the protective layer further comprises zinc.

39. The method of claim 34 wherein the protective layer further comprises 1% zinc.

40. The method of claim 34 wherein the protective layer has a thickness of less than 1200 Angstroms.

41. The method of claim 34 wherein the protective layer has a thickness of less than 600 Angstroms.

42. The method of claim 34 wherein the substrate is chemically stable at temperatures greater than 500° C.

43. The method of claim 34 wherein the substrate is thermally stable at temperatures greater than 500° C.

44. The method of claim 34 wherein the first semiconductor comprises CdS.

45. The method of claim 34 wherein the first semiconductor comprises CdTe.

46. The method of claim 34 further comprising a second semiconductor layer over the first semiconductor layer.

47. The method of claim 46 wherein the second semiconductor layer comprises CdTe.

48. A conductive surface comprising:
a transparent conductive layer on a surface of a substrate; and
a protective layer over the transparent conductive layer, the protective layer isolating the transparent conductive layer, wherein the protective layer includes a tin oxide.
